(19) United States
(12) Patent Application Publication
(10) Pub. No.: US 2014/0154037 A1
(43) Pub. Date: Jun. 5, 2014

(54) METHOD AND SYSTEMS FOR SEMICONDUCTOR CHIP PICK & TRANSFER AND BONDING

(71) Applicant: Amlan Sen, Singapore (SG)

(72) Inventor: Amlan Sen, Singapore (SG)

(73) Assignee: ORION SYSTEMS INTEGRATION PTE LTD, Singapore (SG)

(21) Appl. No.: 14/123,707

(22) PCT Filed: May 31, 2012
(86) PCT No.: PCT/SG2012/000190

§ 371 Date: Feb. 18, 2014

(30) Foreign Application Priority Data
Jun. 3, 2011 (US) 61492824

(51) Int. Cl. H01L 21/687

(52) U.S. Cl. CPC H01L 21/68707
USPC 414/744.2; 414/800

(57) ABSTRACT

Various embodiments provide a system for pick and transfer of semiconductor chips. The system comprises: a rotating arm; two pick up heads attached at respective end portions of the rotating arm; and a camera system for inspecting a chip pick-up position in a vertical line of sight configuration. Also, an axis of rotation of the rotating arm is offset from the line of sight. Various embodiments also provide a corresponding method.

### FIELD OF INVENTION

The present invention relates broadly to method and systems for Semiconductor Chip Pick & Transfer and Bonding

### BACKGROUND

Method and systems for Semiconductor Chip Pick & Transfer and Bonding are widely used in the semiconductor industries, in particular in semiconductor fabs or foundries. Ongoing efforts are being made to improve various aspects of such methods and systems, including with a view to improving throughput, accuracy, reliability, and/or cost associated with the methods and systems.

Furthermore, efforts are also being made with a view to improving the resulting devices, in particular the chip/substrate entity, including the reliability, durability, dimensioning, and/or electrical properties of solder bonds between the chip and the substrate.

Embodiments seek to provide method and systems for Semiconductor Chip Pick & Transfer and Bonding that seek to address one or more of the above improvement efforts.

### SUMMARY

Various embodiments provide a system for pick and transfer of semiconductor chips comprising: a rotating arm; two pick up heads attached at respective end portions of the rotating arm; and a camera system for inspecting a chip pick-up position in a vertical line of sight configuration; wherein an axis of rotation of the rotating arm is offset from the line of sight.

In an embodiment, the pick up heads are angled relative to a longitudinal axis of the rotating arm.

In an embodiment, the pick up heads are moveably attached to the rotating arms.

In an embodiment, the system further comprises means for retracting the pick up heads during rotation of the pick up heads away from the chip pick-up position.

In an embodiment, the means for retracting comprises a cam for guiding the pick up heads during rotation of the rotating arm.

In an embodiment, the camera system comprises a substantially horizontal camera and a reflecting element for achieving the vertical line of sight configuration

Various embodiments provide a method for pick and transfer of semiconductor chips, the method comprising the steps of: providing a rotating arm; providing two pick up heads attached at respective end portions of the rotating arm; providing a camera system for inspecting a chip pick-up position in a vertical line of sight configuration; and rotating the rotating arm for pick and transfer of the semiconductor chips, wherein an axis of rotation of the rotating arm is offset from the line of sight.

Various embodiments provide a device for bonding a semiconductor chip onto a substrate comprising: a pick-up tip for the semiconductor chip; a heater for heating the pick-up tip for heating of the chip prior to bonding; and means for directing a gaseous cooling stream towards the pick-up tip.

In an embodiment, the pick-up tip is attached on a mounting block, and the heater is disposed in the mounting block.

In an embodiment, the means for directing the cooling stream comprises a conduit element mounted to the mounting block.

In an embodiment, the conduit element is mounted to the mounting block via a thermally insulating element.

In an embodiment, the conduit element is configured to direct the cooling stream from three sides of the mounting block.

In an embodiment, the conduit element is configured to receive the cooling stream in a downward direction along one side of the mounting block, and comprises a diverting portion for diverting the cooling stream substantially horizontally towards the pick-up tip mounted at a bottom of the mounting block.

In an embodiment, the diverting portion comprises a ledge extending inwardly towards the pick-up tip.

Various embodiments provide a method of forming a solder joint between a semiconductor chip and a substrate, the method comprising the steps of: melting a solder disposed between the chip and the substrate, the chip and the substrate being separated by a first distance; retracting the chip from the substrate while the solder is in a molten state such that the chip and the substrate are separated by a second distance; and solidifying the solder while the chip and substrate are separated by the second distance.

In an embodiment, the solder is disposed on the chip and melted prior to contact with the substrate.

In an embodiment, the semiconductor chip is preheated to a first temperature lower than the melting temperature of the solder disposed on the chip.

In an embodiment, the solidifying of the solder comprises directing a cooling stream towards the solder.

In an embodiment, the cooling stream is directed towards the solder while a chip and/or substrate heater continue to provide heat to the chip and/or substrate.

In an embodiment, the second distance is chosen such that the formed solder joint has a desired height and/or shape.

In an embodiment, the desired shape of the solder joint comprises an hourglass shape.

Various embodiments provide a method of forming a solder joint between a semiconductor chip and a substrate, the method comprising the steps of: melting a solder disposed between the chip and the substrate; and solidifying the solder by directing a cooling stream towards the solder.

In an embodiment, the cooling stream is directed towards the solder while a chip and/or substrate heater continue to provide heat to the chip and/or substrate.

Various embodiments provide a system for placing a semiconductor chip onto a substrate comprising: a base; a substrate holder moveable relative to the base in an x-y plane parallel to the base; and a bond head moveable substantially only along a fixed vertical axis relative to the base such that x and y positions of the bond head relative to the base are substantially fixed.

In an embodiment, the bond head is mounted to a top plate moveable substantially only along a fixed vertical axis relative to the base.

In an embodiment, the top plate is coupled to two or more vertical shafts mounted to the base.

In an embodiment, the bond head comprises pick-up tip rotatable in a plane parallel to the base.

In an embodiment, the system further comprises means for providing the semiconductor chip to the bond head for pick-up, wherein the means for providing the semiconductor chip is configured for moving in and out of the fixed x and y positions of the bond head.

In an embodiment, the means for providing the semiconductor chip to the bond head for pick-up is configured in use to heat up the semiconductor chip before providing the semiconductor chip to the bond head for pick-up.

In an embodiment, the system further comprises means for inspecting alignment of the semiconductor chip on the bond head and a substrate on the substrate holder, wherein the means for inspecting the alignment is configured for moving in and out of the fixed x and y positions of the bond head.

In an embodiment, the system further comprises means for cooling the semiconductor chip on the bond head.

In an embodiment, the means for cooling comprises means for blowing an airjet onto a portion of the bond head.

Various embodiments provide a method of placing a semiconductor chip onto a substrate comprising the steps of: heating the semiconductor chip, the semiconductor chip having solder thereon and being heated to a temperature which is higher than the solder melting point to form molten solder; heating the substrate to a temperature which is lower than the solder melting point; and placing the semiconductor chip onto the substrate so that the molten solder forms a solder joint therebetween to join the semiconductor chip to the substrate and cause the semiconductor chip and the substrate to reach an equilibrium temperature which is higher than the solder melting point.

In an embodiment, the method further comprises preheating the semiconductor chip to a temperature which is lower than the solder melting point before heating the semiconductor chip to the temperature which is higher than the solder melting point.

In an embodiment, the method further comprises cooling the solder joint to below the solder melting point to solidify the solder.

In an embodiment, the method further comprises waiting a predetermined period of time in between the step of placing and the step of cooling.

In an embodiment, the method further comprises holding the substrate in position using a vacuum before the step of placing.

In an embodiment, the method further comprises pulling apart the semiconductor chip and the substrate after the step of placing to form the solder joint into a predetermined shape.

In an embodiment, the predetermined shape is an hour-glass shape.

Various embodiments provide a system for fluxing semiconductor chips for bonding comprising: a rotary flux plate having pockets; means for dispensing a flux material into the pockets; means for leveling the flux material in the pockets; wherein the system is configured for indexing the pockets in a direction from the means for dispensing to the means for leveling the flux material.

In an embodiment, the means for dispensing the flux material comprises a dispensing conduit mounted to an axial support for the rotary flux plate, wherein a radial position of an outlet of the dispensing conduit is aligned with a radial position of the pockets.

In an embodiment, the means for leveling the flux material comprises a wiper element mounted to the axial support for the rotary flux plate, wherein a radial position of a wiping edge of the wiper element is aligned with the radial position of the pockets.

In an embodiment, the wiping edge is level with a surface of the rotary flux plate.

In an embodiment, the wiper element is mounted to the axial support via the dispensing conduit.

Various embodiments provide a system of selectively fluxing a substrate comprising of: a flux plate having patterned recesses; means for dispensing a flux material into the recesses; means for leveling the flux material in the recesses; and a stamp pad for transferring the flux material in the recesses onto the substrate to apply the flux material to selective locations on a surface of the substrate.

In an embodiment, the stamp pad is configured in use to align along its longitudinal axis with the recesses to pick-up the flux material from the flux plate.

In an embodiment, the means for dispensing the flux material into the recesses comprises a flux material reservoir, and wherein the flux plate is configured in use to move underneath the flux material reservoir to receive the flux material into the recesses.

In an embodiment, the means for leveling the flux material in the recesses comprises a wiper element disposed on the flux material reservoir, and wherein the flux plate is configured in use to move from underneath the flux material reservoir to cause the wiper element to level the flux material in the recesses.

In an embodiment, the system further comprises a camera configured in use to enable inspection of the flux material pattern transferred to the stamp pad.

Various embodiments provide a method of selectively fluxing a substrate, the method comprising the steps of: providing a flux plate having a pattern of flux material provided thereon; picking up the flux material using a stamp pad element such that the pattern of the flux material is transferred to the stamp pad element; and transferring the patterned flux material from the stamp pad element to the substrate.

In an embodiment, the flux plate comprises recesses for holding the pattern of flux material.

In an embodiment, the recesses are aligned with a longitudinal axis of the stamp pad during pick-up of the flux material.

In an embodiment, the method further comprises positioning the flux plate underneath a flux material reservoir, and providing the flux material into the recesses.

In an embodiment, the method further comprises removing the flux plate from underneath the flux material reservoir and leveling the flux material in the recesses.

In an embodiment, a wiper element disposed on the flux material reservoir is used to level the flux material in the recesses during removal of the flux plate from underneath the flux material reservoir.

In an embodiment, the method further comprises inspecting the flux material pattern transferred to the stamp pad element using a camera.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows an overview perspective schematic diagram of a system for high speed precision assembly of semiconductor packages according to an example embodiment.

FIG. 2 shows the different perspective view schematic diagram of the system layout of the system of FIG. 1.

FIG. 3 shows a different perspective view schematic diagram of the system layout of the system of FIG. 1.

FIGS. 4a), 4b) and 4c) shows the schematic diagram of an Offset Flipper according to an example embodiment.

FIG. 5 shows the schematic diagram of a Precision Bond Module according to an example embodiment.

FIG. 6 shows the schematic diagram of a Preheater according to an example embodiment.

FIG. 7 shows the schematic diagram of a Substrate XY Table according to an example embodiment.

FIG. 8 shows the schematic diagram of a Substrate Height Probe according to an example embodiment.

FIG. 9 shows the schematic diagram of an Alignment Camera according to an example embodiment.

FIG. 10 shows the schematic diagram of a Bond Head according to an example embodiment.

FIGS. 11 a) and 11 b) shows the schematic diagram of a Dieset Structure according to an example embodiment.

FIGS. 12a), 12b), 12c), and 12d) and enlargement 502 illustrate the operations of a Precision Bond Module process according to an embodiment.

FIG. 13 illustrates the temperature profile of semiconductor chip and substrate during the Precision Bond Module operations of FIG. 12.

FIGS. 14a) to c) show schematic drawings illustrating methods of forming a solder joint between a semiconductor chip and a substrate according to example embodiments.

FIG. 15 shows the schematic diagram of a Selective Fluxing Unit according to an example embodiment.

FIGS. 16a), 16b), 16c) and 16d) illustrate the sequence of steps during the selective fluxing operation in one example embodiment.

FIG. 17 shows the schematic diagram of a Rotary Flux Plate according to an example embodiment.

### DETAILED DESCRIPTION

The present invention may be understood more readily by reference to the following detailed description of certain embodiments of the invention. While the following description of the semiconductor package assembly system will use specific drawings for illustrating the principles of the present invention, it is apparent that the principles of the present invention are not limited by these specifics.

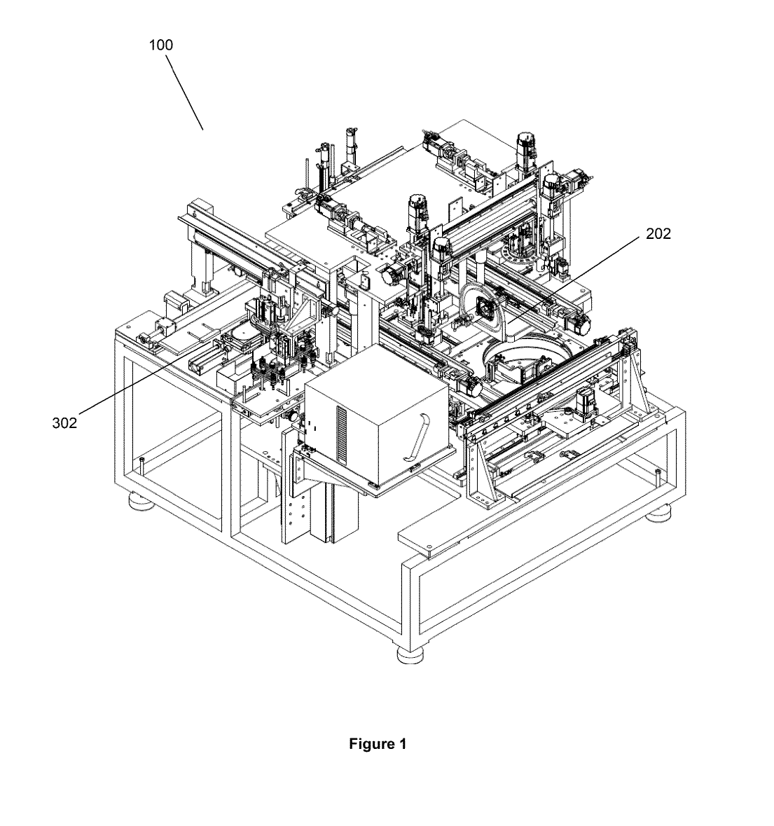

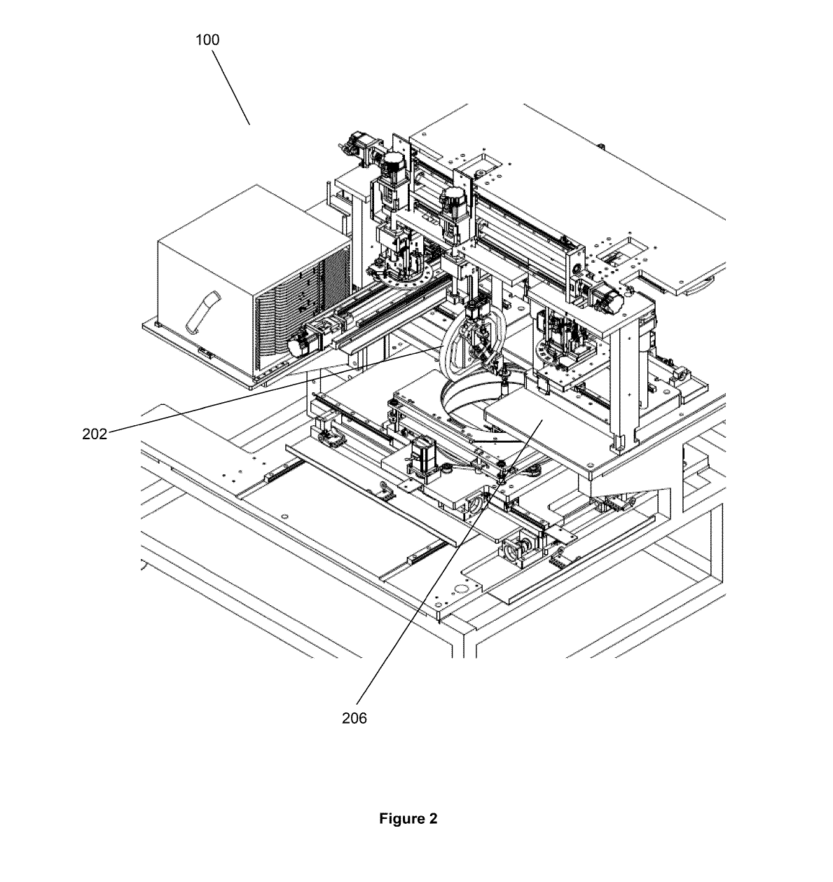

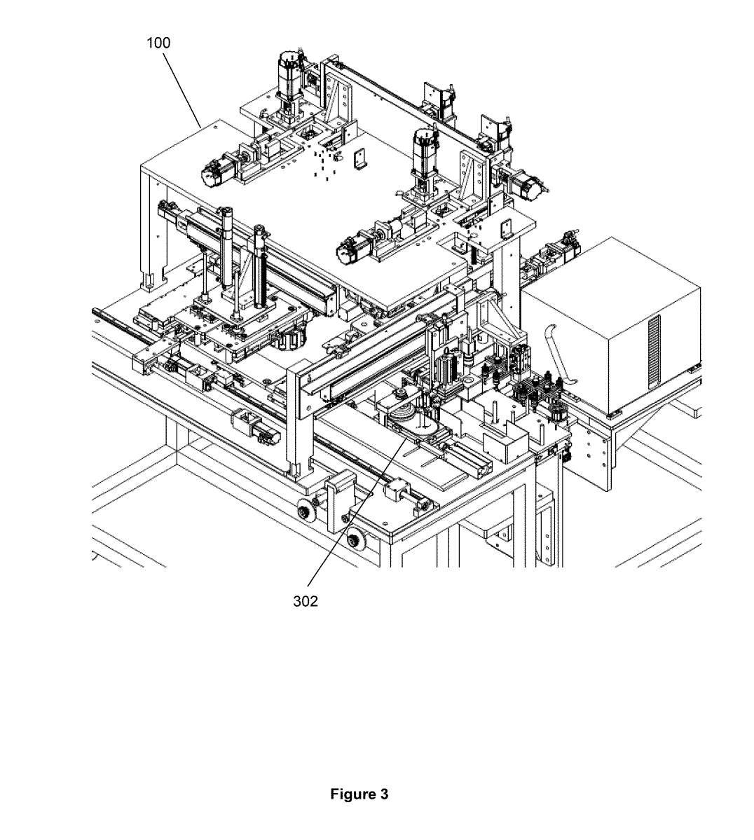

The present invention provides an apparatus that is capable of processing semiconductor chips in a precise way with high throughput, where the processes include mechanical motion of flipping, picking and placing of semiconductor chips onto substrate. In an embodiment, the semiconductor chip is a flip chip. FIGS. 1 to 3 show schematic diagrams of different perspective views of an apparatus 100 for high speed precision assembly of semiconductor packages according to an example embodiment. Several functions of the apparatus are performed by several modules including an Offset Flipper Module 202, a Precision Bond Module 206 and a Selective Fluxing Module 302. Depending on the application configuration, chip pre-heating in the Precision Bond Module 206 is used in conjunction with the Selective Fluxing Module 302 as will be described in more detail below.

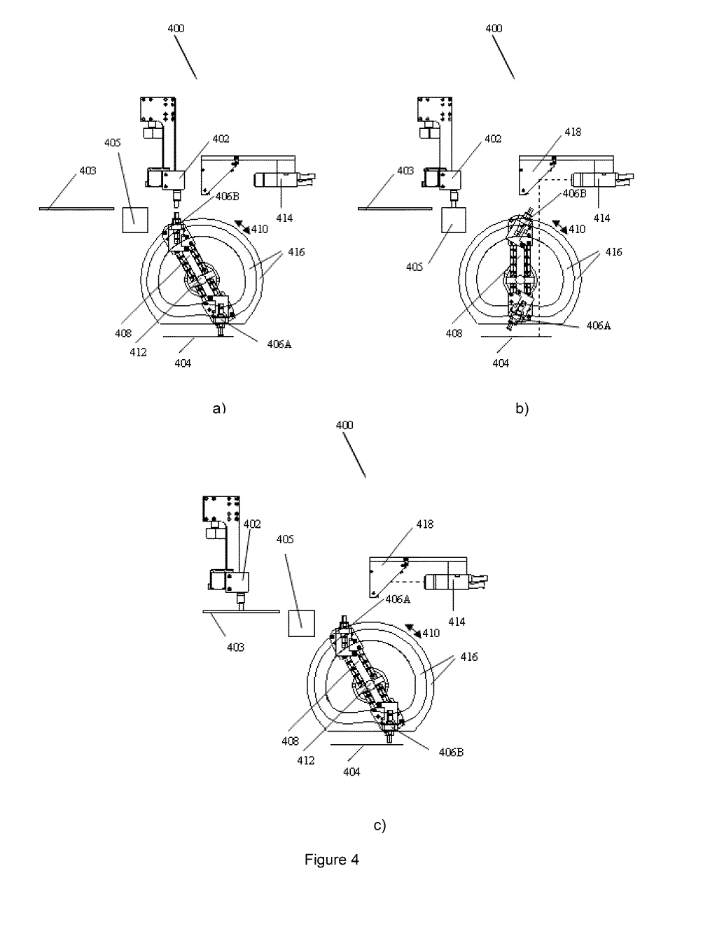

FIGS. 4a), b) and c) show an exemplary embodiment of the apparatus, the Offset Flipper Module 400, which picks up semiconductor chip from diced wafer to be transferred to a Transfer Head 402, for measuring of the semiconductor chip dimensions and transferring to a Preheater 403 to be placed on a substrate in a later process. The Offset Flipper Module 400 also includes a chip height probe 405 for measuring a vertical position (i.e. height) of the semiconductor chip. It can be seen as shown in FIG. 4a), from a diced wafer 404, which is mounted on tape (not shown), individual semiconductor chips are ejected with a die ejector (not shown) from below upwards, to push/eject the chip out of the tape (not shown), while the tape (not shown) is being held down by vacuum or mechanical means. Pick Up Head 406 then picks a chip from the diced wafer by a synchronized motion between the Pick Up Head 406A and the die ejector (not shown). The Pick Up Heads 406A, B can be any known means in the art such as vacuum sucker that picks up the chip with air pressure and subsequently transfers the chip by releasing the pressure. To efficiently eject and pick up a chip, the chip has to be at a predetermined position aligned to the centre of the die ejector (not shown). The positioning of this chip is achieved with a vision alignment system (not shown) looking at the chip.

The Pick Up Heads 406A, B are mounted on a Pick and Flip Arm 408. The Pick and Flip Arm 408 is arranged in such a way that it rotates in an executed rotation as indicated by arrow 410 about a pivot point 412, thus flipping the picked up chip by 180 deg. The Pick and Flip Arm 408 has two opposite Pick Up Heads 406A and 406B, which allows simultaneous picking up and depositing of two semiconductor chips, which have been ejected from the diced wafer. The first Pick Up Head 406A picks up a chip, while the second Pick Up Head 406B deposits previously picked up chip, which is now flipped, onto the Transfer Head 402. In this position, the Pick and Flip Arm 408 is angled to the vertical axis and the Pick Up Head 406A, B does not lie on the same vertical axis.

As shown in FIG. 4b), the Offset Flipper Module 400 is able to perform vision check for chips prior to pick up when the Pick and Flip Arm 408 swings to a vertical position from the pick and deposit position (compare FIG. 4a) to clear the view for the camera 414 in the vision system (not shown). The vision system locates/inspects for proper die location so as to provide information to the chip alignment system (not shown) to perform chip alignment to the die ejector (not shown), prior to pick up by the Pick Up Head 406. Besides the Pick and Flip Arm 408 rotating about the pivot point 412, the Pick Up Heads 406A also travel in the plane of the drawings as caused by a cam 416. This results in control of the Z motion of the Pick and Flip Arm 408 with the Pick Up Heads 406A, B at the bottom of the Offset Flipper Module 400 to prevent contact with the diced wafer 404 during rotation.

FIG. 4c) shows further operation of the Offset Flipper Module 400, wherein the Pick and Flip Arm 408 has rotated to an opposite position to that of FIG. 4a). Stated differently, in FIG. 4c), the Pick and Flip Arm 408 has swung 180 degrees from the position shown in FIG. 4a).

A chip will be transferred from the Pick Up Heads 406A, B to the Transfer Head 402 with the positioning of the Pick and Flip Arm 408 as shown in FIG. 4a), which will then transfer the chip to be processed in the Precision Bond Module 206 (FIGS. 1-3).

The example embodiment described above advantageously provides a system for pick and transfer of semiconductor chips in the form of the Offset Flipper Module 400, comprising the rotating Pick and Flip Arm 408, two pick up heads 406A, B attached at respective end portions of the Pick and flip Arm 408, and a camera system including camera 414 for inspecting a chip pick-up position in a vertical line of sight configuration, wherein an axis of rotation of the Pick and Flip Arm 408 is offset from the line of sight. The pick up heads 406A, B are angled relative to a longitudinal axis of the Pick and flip Arm 408, and are moveably attached thereto.

The Offset Flipper Module 400 further comprises means for retracting the pick up heads during rotation of the pick up heads 406A, B away from the die-pick-up position, in the form of a cam 416 for guiding the pick up heads 406A, B during rotation of the Pick and Flip Arm 408, in this example embodiment. The camera system comprises the substantially horizontal camera 414 and a reflecting element in the form of a mirror 418 for achieving the vertical line of sight configuration

The example embodiment can provide a method for pick and transfer of semiconductor chips. In an embodiment, the semiconductor chip is a flip chip. In an embodiment, the method comprises the steps of providing a rotating arm, providing two pick up heads attached at respective end portions of the rotating arm, providing a camera system for inspecting a die pick-up position in a vertical line of sight configuration; and rotating the rotating arm for pick and transfer of the semiconductor chips, wherein an axis of rotation of the rotating arm is offset from the line of sight.

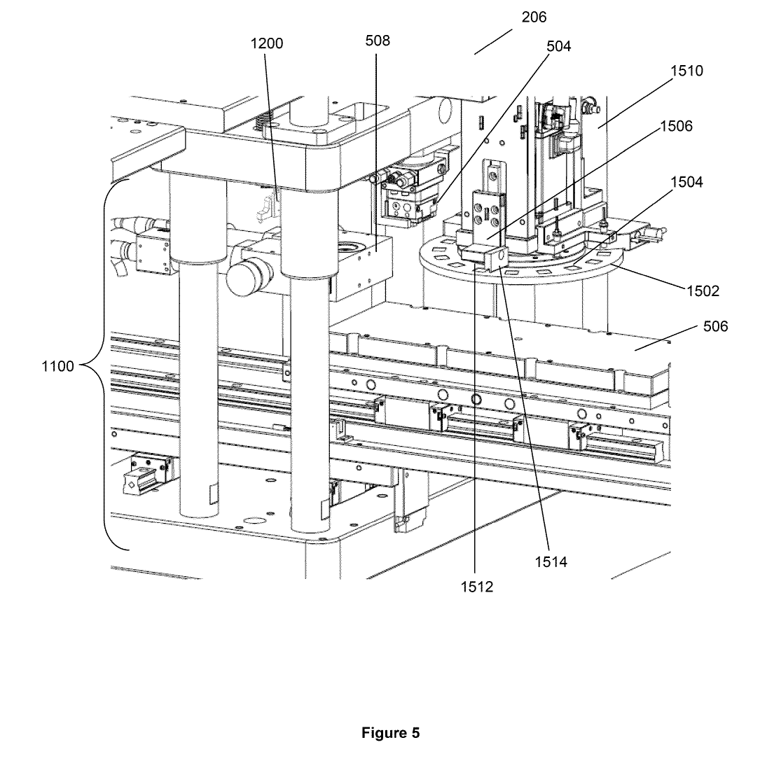

FIG. 5 illustrates the Precision Bond Module 206 in an exemplary application configuration for bonding the semiconductor chips comprising interconnections such as copper pillar bumps to a substrate. The Precision Bond Module 206 as shown in FIG. 5 consists of the Bond Head 504 with airjet cooling channel (not visible in this view), the Substrate XY Table 506, the Alignment Camera 508, the Die-set Structure 1100, a Substrate Height Probe 1200, and a Rotary Preheater 1502.

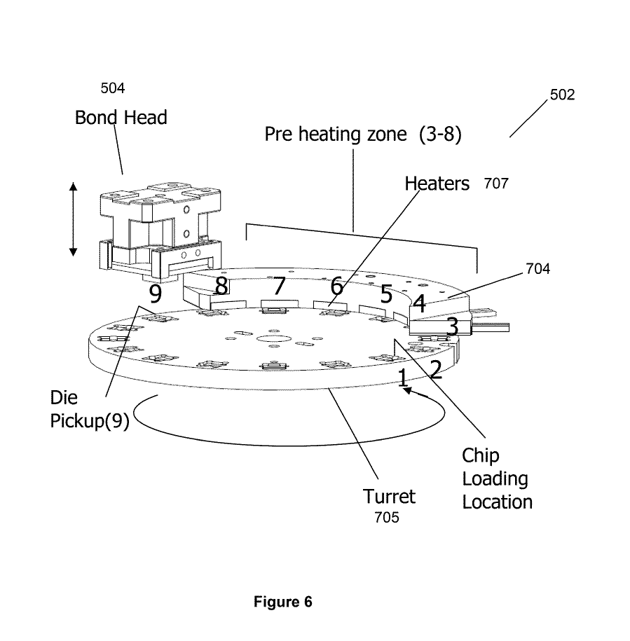

FIG. 6 shows the Rotary Preheater 502. This Rotary Preheater 502 receives the chip from the Transfer Head 402 and performs a preheating process in which the chip undergoes gradual heating from room temperature to a first temperature preferably below the melting point of a solder, so as to preferably assist in preventing thermal shock on the chip. The Rotary Preheater 502 includes an indexing mechanism (not shown) to drive the Turret 705 carrying the chips, Heater Block 704 and a means to maintain a gap between the Heater Block 704 and the Turret 705. The chip is placed on and indexed around the Turret 705, and heated by radiation and convection from the Heating Block 704, which incorporates several Heater Elements 707 disposed above indexing locations of the chips on a Turret 705. Details of the Rotary Preheater 502 for use in example embodiments have been described in published PCT application no. PCT/SG2007/000441, the contents of which are hereby incorporated by cross-reference. The pre-heated chip will then be picked up by the Bond Head 504.

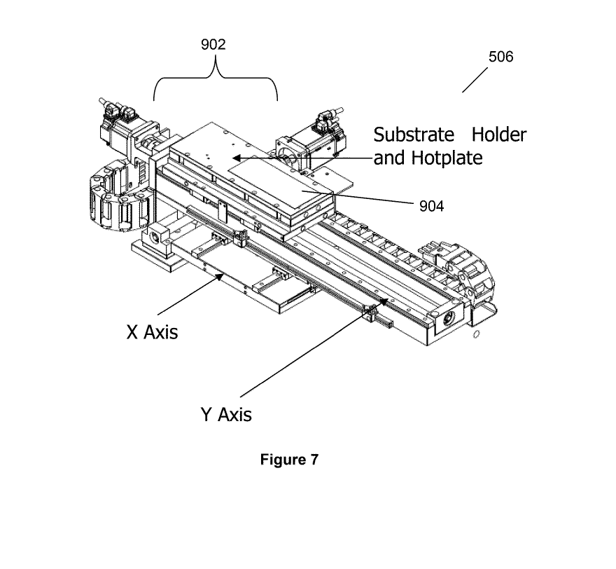

FIG. 7 shows the Substrate XY Table 506. This Substrate Table 506 comprises of a vacuum chuck/clamps with built in heating components (not shown) and a motorised XY stage 902. The operating procedure in one embodiment can be as follows; to hold down the substrate 904 firmly by means of vacuum/clamps (not shown) during the entire bonding process, to heat up the substrate 904 to a second temperature, to enable the substrate 904 on the XY stage 902 to be moved to various bonding locations and for making fine movements for offset correction during alignment.

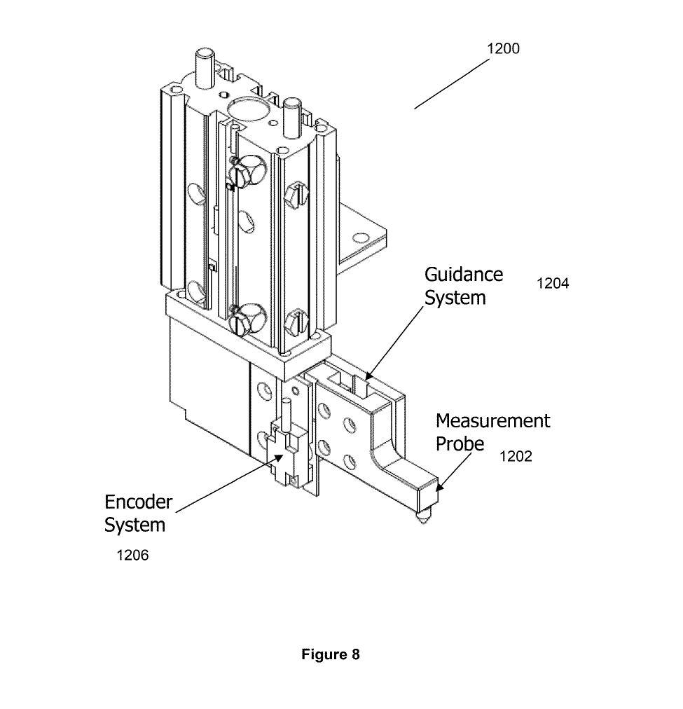

FIG. 8 shows a Substrate Height Probe 1200. The Substrate Height Probe 1200 allows the height of the substrate to be measured after it has been firmly held by the Substrate XY Table 506 (FIG. 5). The Substrate Height Probe 1200 comprises a probe element 1202, a guidance system 1204 for vertical displacement of the probe element 1202, and a precision measurement scale and encoder 1206 coupled to the guidance system 1204.

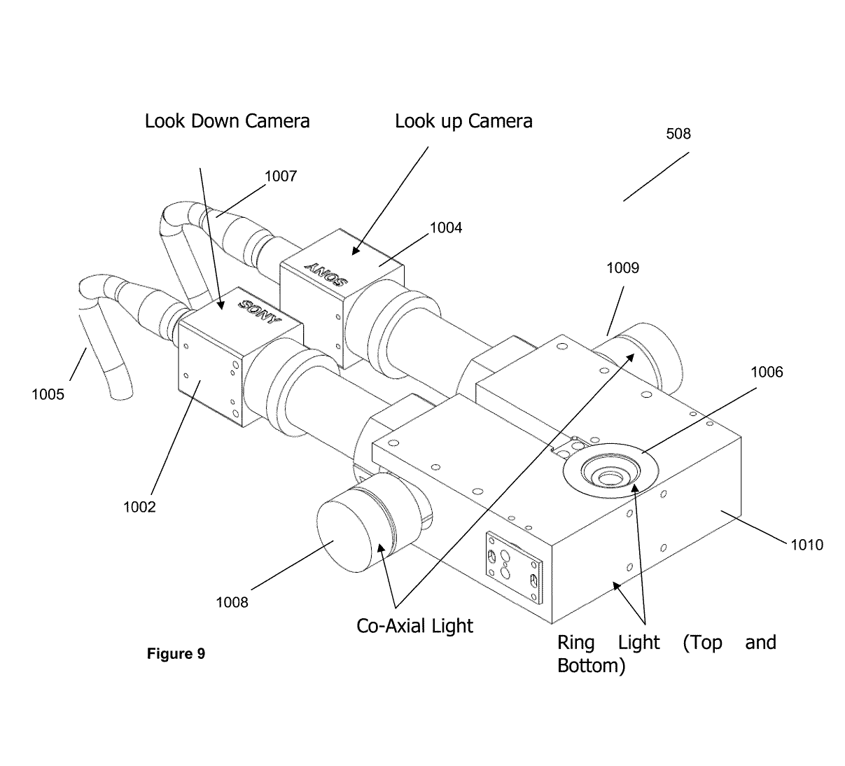

FIG. 9 shows the Alignment Camera 508. The Alignment Camera 508 uses collinear vision alignment cameras 1002, 1004 to capture and process the images of fiducial points on the chip and substrate concurrently and provision of the data to controller (not shown) via cables 1005, 1007 to calculate the relative offset in XY coordinates and the theta offset. The Alignment Camera 508 comprises the pair of cameras 1002 and 1004, one each for chip and substrate, top and bottom ring light 1006, which would be effective for images of chips/substrates with protruded features e.g. bumps, coaxial light 1008, 1009, which would be effective for images of chips/substrates with flat reflective surfaces e.g. wafer surface. Optical elements (not shown) are disposed in the housing 1010 to create the optical paths from the cameras 1002 and 1004 to respective co-axial lenses e.g. 1012. The Alignment Camera 508 can be driven in the XYZ axis by a motor (not shown).

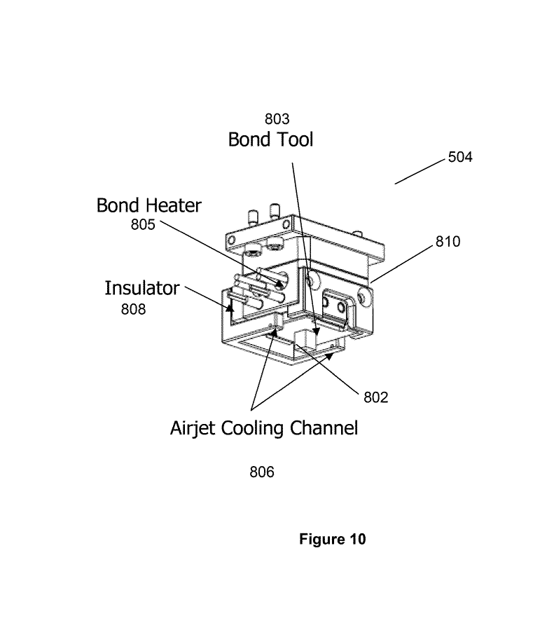

The Bond Head 504 is shown in FIG. 10, and allows the chip to be heated to a third temperature preferably above the melting point of the solder on the bumps, such that there is sufficient thermal energy for a solder joint. The Bond Head 504 can be mounted on the Dieset 510 (FIG. 5) and coupled with a motor for die rotation during an alignment process prior to bonding. Upon contact between the pre-heated die and the pre-heated substrate, the junction temperature of the chip and the substrate reaches an equilibrium fourth temperature, which is preferably higher than the melting point of the solder. Following a bonding period, the Bond Head 504 enables solidification of the molten solder by momentarily cooling down the otherwise hot Bond Tool 803 by a concentrated and guided stream of compressed air onto the tip 802 of the Bond Tool 803. As will be appreciated, this can preferably facilitate faster cooling of the junction temperature to below the solder melting point. Also, this can preferably allow the bond heater 805 to remain heated, thus maintaining the Bond Head 504 at a substantially constant temperature between pick-up and bonding of chips, which can in turn result in faster processing time and/or more stable operation conditions. The Bond Tool 803 is preferably made of a material with high thermal conductivity and low specific heat capacity properties. A cooling channel 806 to carry and focus the jet of air to the tip 802 of the Bond Tool 803 is separated from the body of the Bond Head 504 by an insulating plate 808.

The example embodiment described above advantageously provides a device for bonding a semiconductor chip onto a substrate in the form of Bond Head 504 comprising the pick-up tip 802 for the chip, the heater 805 for heating the pick-up tip 802 for heating of the chip prior to bonding, and means for directing a gaseous cooling stream towards the pick-up tip 802, here in the form of the airjet cooling channel 806 mounted to a main mounting block 810 of the Bond head 504. The pick-up tip 802 is attached on the mounting block 810, and the heater 805 is disposed in the mounting block 810. The cooling channel 806 is mounted to the mounting block 810 via the thermally insulating plate 808. In this embodiment, the cooling channel 806 is configured to direct the cooling stream from three sides of the mounting block 810 towards the pick-up tip 802. The cooling channel 806 is configured to receive the cooling air stream in a downward direction along one side of the mounting block 810, and has a diverting portion, here in the form a ledge 812 extending inwardly towards the pick-up tip 802, for diverting the cooling stream substantially horizontally towards the pick-up tip 802 mounted at the bottom of the mounting block 810.

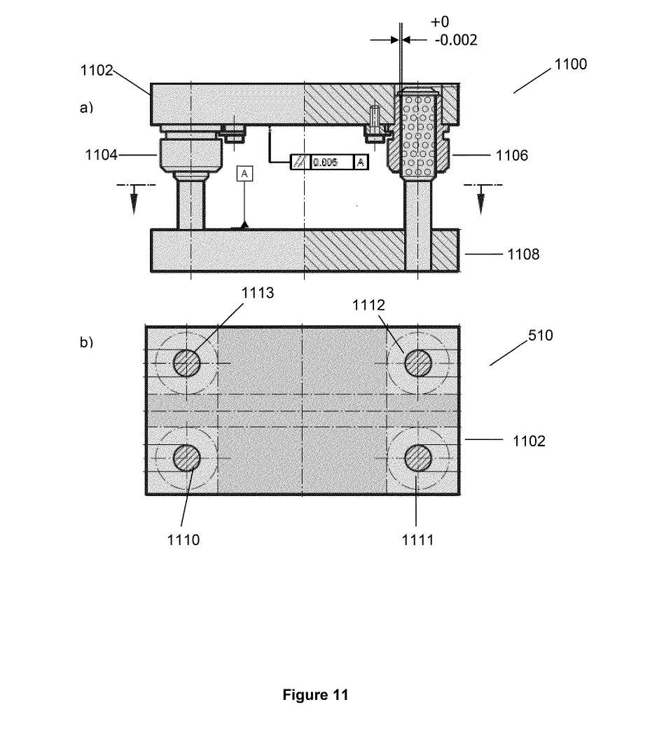

FIG. 11a) and b) shows a Dieset Structure 1100 according to an example embodiment. The Dieset Structure 1100 provides a structure to deliver high degree and long lasting parallelism between the Bond Head 504 (FIG. 5) and the XY Table 506 (FIG. 5). The Dieset Structure 1100 consists of a Dieset top plate 1102, with an interference fit in a ball-shaft assembly (e.g. 1104, 1106 to a bottom Dieset plate 1108.) This assembly preferably allows maximum rigidity and minimum radial shift during vertical motion. A motorized actuator (not shown) enables the relative motion between the Dieset plates 1102, 1108. The presence of a measurement system (not shown) allows precise measurement of displacement between the two plates 1102, 1108 of the Dieset Structure 1100. In this embodiment, the Dieset plates 1102, 1108 are coupled via fours shafts 1110 to 1113 for allowing maximum rigidity and minimum radial shift during the vertical motion.

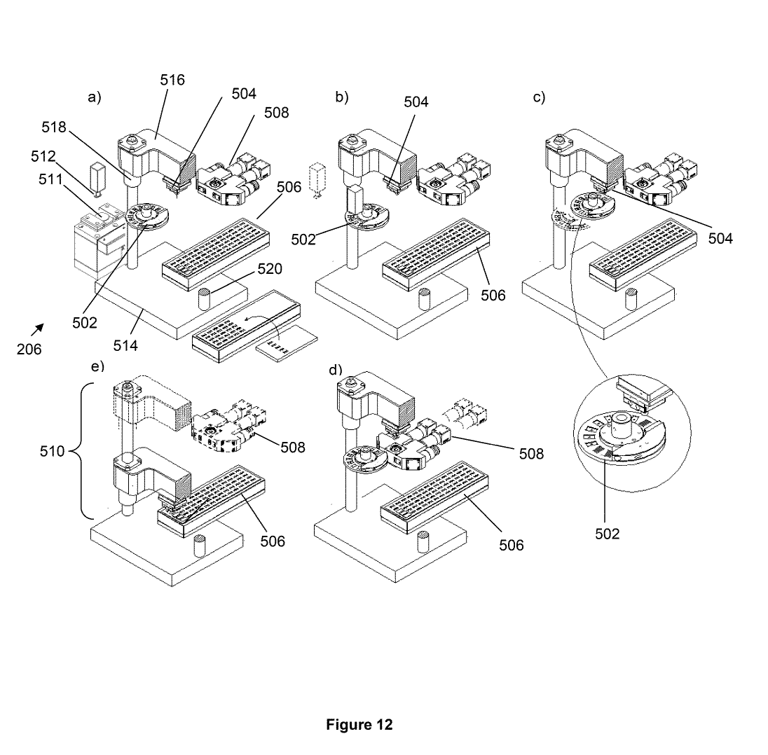

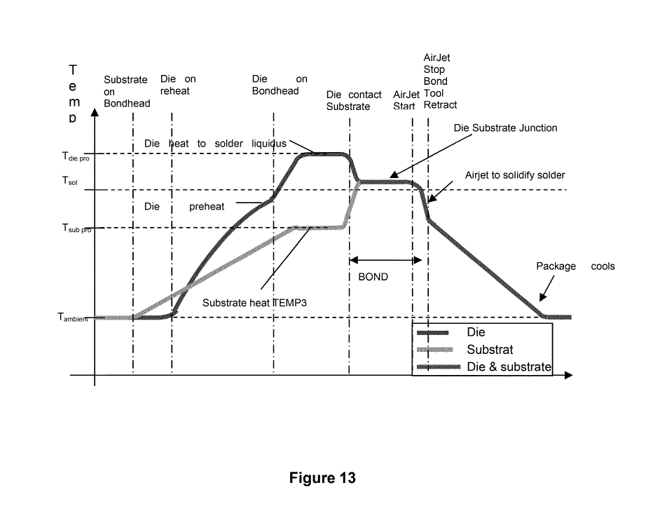

FIG. 12a) to e) illustrate the sequence of activities that take place in the Precision Bond Module 206 in one application configuration. FIG. 13 shows the associated temperature profile during the sequence of activities. When a chip first arrived at the Precision Bond Module 206 from the Offset Flipper 400 (FIG. 4), the chip height is measured (FIG. 12a) using a chip height probe 511, (measurement location 512) and the chip is dispensed onto a Rotary Preheater 502 (FIG. 12b). The Rotary Preheater 502 heats up the chip to a temperature 1 and the pre-heated chip is then handed over to a Bond Head 504 (FIG. 12c), on which the chip is further heated to a temperature (temperature 2) higher than the solder melting point. Also during the step shown in FIG. 12a) a substrate is dispensed onto a Substrate XY Table 506 and being held down by strong vacuum. The substrate will be heated to a temperature 3 on the Substrate XY Table 506. The height of the substrate is measured post-heating by a Substrate Height Probe (not shown). The Substrate XY Table 506 then moves to the bonding location.

As shown in FIG. 12d), an Alignment Camera 508 moves in between the Substrate XY Table 506 and the Bond Head 504 and processes fiducial marks on chip and substrate using collinear vision to determine the relative offset in XY and theta directions between the die on the Bond Head 504 and the relevant bond location on the Substrate XY Table 506. The alignment Camera 508 then retracts (FIG. 12e). The Bond Head 504 mounted on the Dieset 510 makes a theta correction and the XY Table 506 makes the correction in the X and Y axis. The Dieset 510 makes a calculated vertical bond stroke downward based on the height calculated by the controller (not shown). Upon contact, the junction of the chip and the substrate reaches an equilibrium temperature 4, which is higher than the melting point of solder. With reference to FIG. 13, which shows the temperature profiles of the chip and substrate during the operations described, the chip and the substrate are held at the temperature 4 for a certain time sufficient for the solder bond to occur. The Bond Head 504 airjet cooling channel then blows air to the tip of the bond tool to drop the junction temperature (temperature 5) of the chip and substrate below the melting point of solder. The Bond Head 504 then releases the chip and the Dieset 510 retracts the Bond Head 504.

The example embodiment described above advantageously provides a system for placing a semiconductor chip onto a substrate in the form of Dieset 510 comprising a base in the form of a base plate 514, a substrate holder in the form of XY table 506 moveable relative to the base plate 514 in an x-y plane parallel to the base plate 514, and the Bond Head 504 moveable substantially only along a fixed vertical axis relative to the base plate 514 such that x and y positions of the Bond Head 504 relative to the base plate 514 are substantially fixed. The Bond Head 504 is mounted to a top plate 516 moveable substantially only along the fixed vertical axis relative to the base plate 514. The top plate 516 is coupled to two or more vertical shafts 518, 520 mounted to the base plate 514. The Bond Head comprises pick-up tip rotatable in a plane a parallel to the base plate 514. The Dieset 510 further comprises means for providing the semiconductor chip to the bond head for pick-up, here in the form of a Preheater 502 configured for moving in and out of the fixed x and y positions of the Bond Head 504. The Dieset 510 further comprises means for inspecting alignment of the semiconductor chip on the bond head and a substrate on the substrate holder, here in the form of Alignment Camera 508 configured for moving in and out of the fixed x and y positions of the Bond Head 504. In an embodiment, the semiconductor chip is a flip chip.

In one example embodiment, the bond stroke calculation is based on chip, substrate, reference heights, which are all machine measured, and compression, which is a value to overcome any co-planarity variances from the chip and the substrate and also to obtain the desired standoff between the chip and substrate. In an embodiment, the chip height is measured using a chip height probe 509. In an embodiment, the substrate height is measured using the substrate height probe 1200. The reference height is the vertical distance between the surface of the Substrate XY Table 506 and the surface of the Bond tool tip 802 (FIG. 10). The bond vertical stroke is obtained by calculating the difference between the reference height and the substrate and the die heights, and then adding the compression value. After reaching the bond stroke, where the solder in a liquid state makes contact for bonding, a small pullback stroke can be introduced to displace the chip away from the substrate to obtain a desired solder shape and a desired height, for example, an hourglass shape. The bond head airjet cooling channel then blows air to the tip of the bond tool to drop the temperature of the chip and substrate below the melting point of solder to solidify the solder to retain the height/shape formation. The bond head then releases the chip and retracts fully away from the substrate.

In an embodiment, the Bond Head 504 may be maintained at a constant temperature during the bonding process, and this temperature may be higher than the melting point of the solder. In an embodiment, there may be no heating or cooling from the Bond Head 504. Instead, an instantaneous dip in temperature to solidify the solder joint may be provided by the airjet stream targeted at the Bond tool tip 802 which interfaces between the Bond Head 504 and the chip. Accordingly, the bulk of the system does not need to go through temperature changes.

In an embodiment, the Preheater 502 provides a gradual rise in chip temperature to reduce the temperature differential between the chip and the Bond Head 504. In turn, this may prevent thermal shock when the Bond Head 504 picks up the chip.

It will be appreciated that the solder can be melted by various different methods in different embodiments, including “Melt and Touch” i.e. the solder on the die is molten prior to contact on the substrate, upon contact to the substrate the molten solder reflows onto corresponding pads/bumps on the substrate; “Touch and Melt”, i.e. the die reaches a temperature higher than the melting point of solder, upon contact to the substrate the heat from the die melts the solder on the corresponding pads/bumps on the substrate, or the die is at a temperature lower than the melting point of solder, upon contact to the substrate, heat is applied to the die to melt the solder.

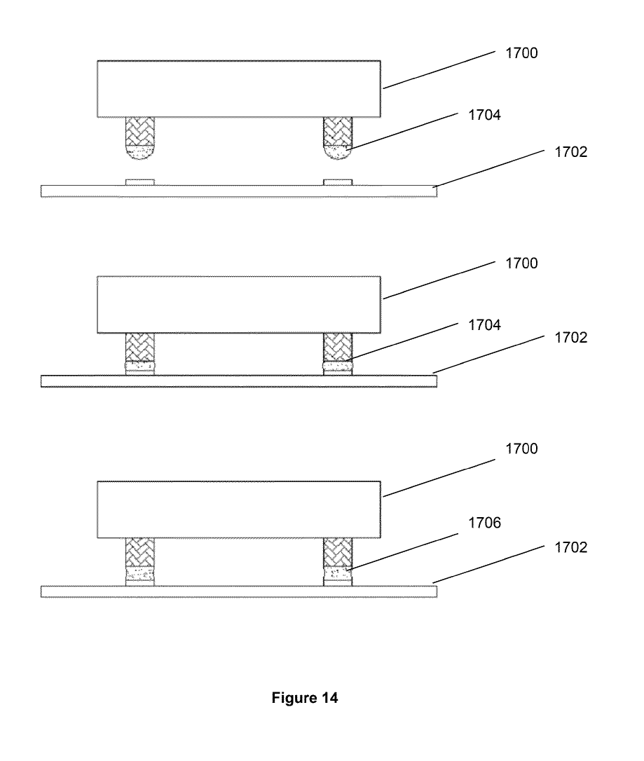

With reference to FIG. 14a) to c), the example embodiments described above advantageously provide a method of forming a solder joint between a die 1700 and a substrate 1702, the method comprising the steps of melting a solder 1704 disposed between the die 1700 and the substrate 1702, the die 1700 and the substrate 1702 being separated by a distance d1, retracting the die 1700 from the substrate 1702 while the solder 1704 is in a molten state such that the die 1700 and the substrate 1702 are separated by a distance d2, and solidifying the solder 1704 while the die 1700 and substrate 1702 are separated by distance d2. The solidifying of the solder 1704 comprises directing a cooling stream towards the solder 1702. The cooling stream is directed towards the solder 1704 while a die and/or substrate heater (not shown) continue to provide heat to the die 1700 and/or substrate 1702 in this embodiment. The distance d2 is chosen such that the formed solder joint 1706 has a desired height and/or shape. The desired shape may comprise an hourglass shape.

Also with reference to FIG. 14a) to c), the example embodiments described above advantageously provide a method of forming a solder joint between the die 1700 and the substrate 1704, the method comprising the steps of melting a solder 1704 disposed between the die 1700 and the substrate 1702, and solidifying the solder 1704 by directing a cooling stream towards the solder 1704. The cooling stream is directed towards the solder 1704 while the die and/or substrate heater (not shown) continue to provide heat to the die 1700 and/or substrate 1702, in this embodiment.

It will be appreciated by a person skilled in the art, that various solder configuration and techniques may be applied in different embodiments. For example, solder bumps may be provided on the die and/or the substrate, and the bonding may involve heating the die and/or the substrate within the Precision Bond Module 206, or in a separate re-flow oven.

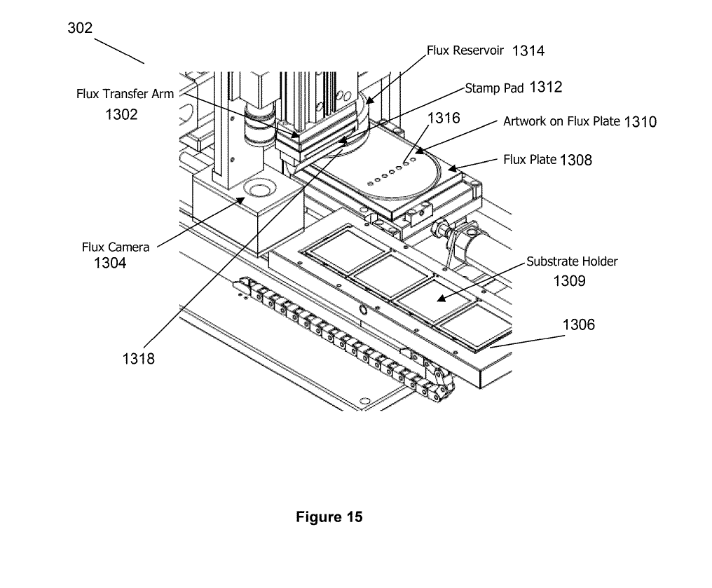

FIG. 15 shows the Selective Fluxing Module 302. The Selective Fluxing Module 302 comprises of a Flux Transfer Arm 1302, Flux Camera 1304, Substrate Holder 1306, Flux Plate 1308, Artwork on Flux Plate 1310, Stamp Pad 1312 and Flux Reservoir 1314. This Selective Fluxing Module 302 operates in the step illustrated in FIG. 12a) to apply flux on selective locations on the surface of a substrate 1309. The Artwork 1310 defines the corresponding selective locations that are to be fluxed on the substrate 1309.

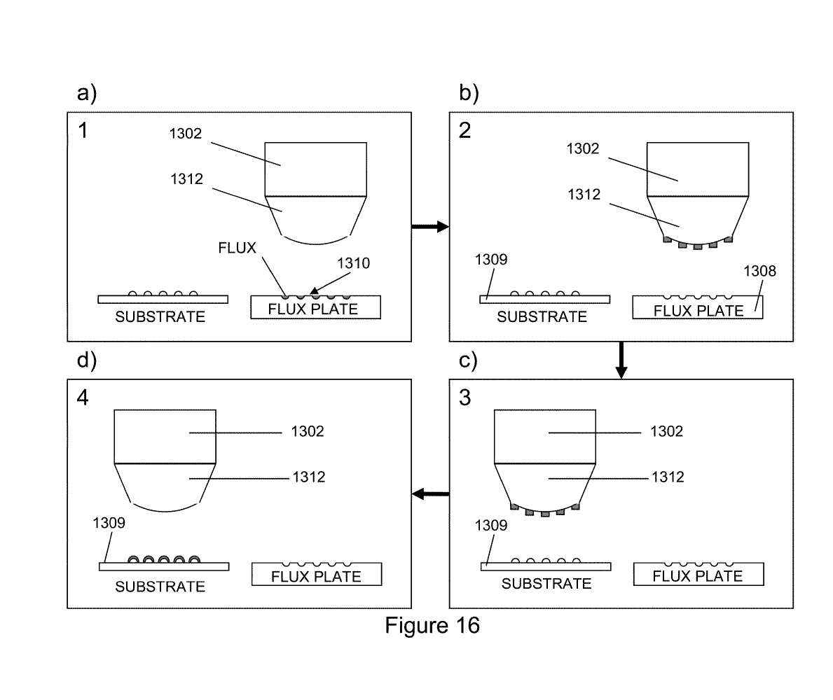

FIG. 16a) to d) illustrate the sequence of steps during the selective fluxing operation in one example embodiment. Step 1 (FIG. 16a) shows Stamp Pad 1312 positioned over Artwork 1310 filled with flux. In step 2 (FIG. 16b) the Stamp Pad 1312 picks up flux from the Flux Plate 1308 and then aligns to the substrate 1309 in step 3 (FIG. 16c) based on information from the look down substrate camera 1300 (FIG. 15). The Stamp Pad 1312 then transfers the flux onto the substrate 1309, for example onto solder bumps 1402, in step 4 (FIG. 16d).

The example embodiment described above advantageously provides a method of selectively fluxing of a substrate, the method comprising the steps of providing the flux plate 1308 having a pattern of flux material, here in the form of artwork 1310 provided thereon, picking up the flux material using the Stamp Pad 1312 such that the pattern of the flux material is transferred to the Stamp Pad 1312, and transferring the patterned flux material from the Stamp Pad 1312 to the substrate 1309. The artwork 1310 comprises recesses e.g. 1316 for holding the pattern of flux material. The recesses 1316 are aligned with a longitudinal axis of the Stamp Pad 1312 during pick-up of the flux material. The method further comprises positioning the flux plate 1308 underneath the flux material reservoir 1314, and providing the flux material into the recesses e.g. 1316. The method further comprises removing the flux plate 1308 from underneath the flux material reservoir 1314 and leveling the flux material in the recesses e.g. 1316. A wiper element, here in the form of a radial wiper 1318 disposed on the flux material reservoir 1314, is used to level the flux material in the recesses e.g. 1316 during removal of the flux plate 1308 from underneath the flux material reservoir 1314. The method further comprises inspecting the flux material pattern transferred to the Stamp Pad 1312 using the camera 1300.

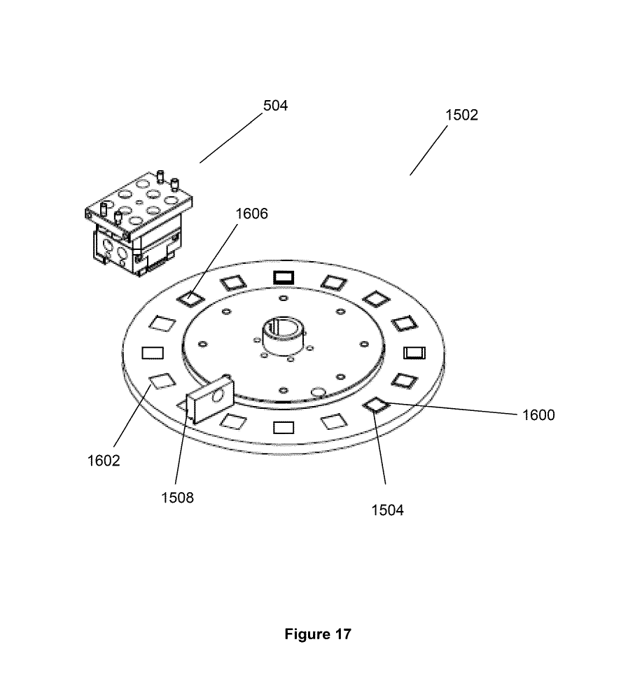

FIG. 17 shows the Rotary Flux Plate 1502 which may replace the Rotary Preheater in an alternative configuration, the chip Pick and Place Arm 402 (FIG. 4) provided to pick up the die from the Pick and Flip Arm 408 (FIG. 4) dispenses the die onto the Rotary Flux Plate 1502 that indexes at fixed intervals. Chips e.g. 1600 can be dispensed following each index of the Rotary Flux Plate 1502. The Rotary Flux Plate 1502 provides multiple pockets e.g. 1504 having predetermined depths and area for filling with flux using the dispensing channel 1506 (FIG. 5). The wiper 1508 levels out the flux in the pockets e.g. 1602. Chips e.g. 1600 being dispensed into the pockets e.g. 1504 of flux would thus have a predetermined flux height on the bumps (not shown). The Bond Head 504 picks up the fluxed chip e.g. 1606 for bonding to the substrate (not shown). It is noted that bonding between the substrate and the chips may proceed within the Precision Bond Module without pre-heating of the chip in this alternative configuration.

The example embodiment described above advantageously provides a system for fluxing semiconductor chips for bonding, comprising the rotary flux plate 1502 having pockets e.g. 1504, means for dispensing a flux material into the pockets e.g. 1504, here in the form of a dispensing channel 1506, and means for leveling the flux material in the pockets e.g. 1504, here in the form of a wiper 1508. The rotary flux plate 1502 is configured for indexing the pockets e.g. 1504 in a direction from the dispensing channel 1506 to the wiper 1508. The dispensing channel 1506 is mounted to an axial support 1510 for the rotary flux plate 1502, wherein a radial position of an outlet 1512 of the dispensing channel is aligned with a radial position of the pockets e.g. 1504. The wiper 1508 is mounted to the axial support 1510 for the rotary flux plate 1502, wherein a radial position of a wiping edge 1514 of the wiper 1508 is aligned with the radial position of the pockets 1504. The wiping edge 1514 is level with a surface of the rotary flux plate 1502, and is mounted to the axial support 1510 via the dispensing channel 1506 in this embodiment. In an embodiment, the semiconductor chip is a flip chip.

Some of the above-described embodiments disclose the use of dies. It is to be understood that in an embodiment, a die comprises one or more integrated circuits which are to become a semiconductor chip. Accordingly, in an embodiment, the terms ‘die’ and ‘semiconductor chip’ may be interchangeable.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A system for pick and transfer of semiconductor chips comprising:
a rotating arm;
two pick up heads attached at respective end portions of the rotating arm; and
a camera system for inspecting a chip pick-up position in a vertical line of sight configuration;
wherein an axis of rotation of the rotating arm is offset from the line of sight.

2. The system as claimed in claim 1, wherein the pick up heads are angled relative to a longitudinal axis of the rotating arm.

3. The system as claimed in claim 1, wherein the pick up heads are moveably attached to the rotating arm.

4. The system as claimed in claim 3, further comprising means for retracting the pick up heads during rotation of the pick up heads away from the chip pick-up position.

5. The system as claimed in claim 4, wherein the means for retracting comprises a cam for guiding the pick up heads during rotation of the rotating arm.

6. The system as claimed in claim 1, wherein the camera system comprises a substantially horizontal camera and a reflecting element for achieving the vertical line of sight configuration

7. A method for pick and transfer of semiconductor chips, the method comprising:
providing a rotating arm;
providing two pick up heads attached at respective end portions of the rotating arm;
providing a camera system for inspecting a chip pick-up position in a vertical line of sight configuration; and
rotating the rotating arm for pick and transfer of the semiconductor chips, wherein an axis of rotation of the rotating arm is offset from the line of sight.

8.-56. (canceled)
